(19) United States
(12) Patent Application Publication
(10) Pub. No.: US 2024/0235233 A1
(43) Pub. Date: Jul. 11, 2024

(54) SHARED CURRENT SENSING UNIT

(71) Applicants: Advanced Micro Devices, Inc., Santa Clara, CA (US); ATI Technologies ULC, Markham (CA)

(72) Inventors: David King Wai Li, Austin, TX (US); Amanullah Samit, Markham (CA)

(73) Assignees: Advanced Micro Devices, Inc., Santa Clara, CA (US); ATI Technologies ULC, Markham (CA)

(21) Appl. No.: 18/405,800

(22) Filed: Jan. 5, 2024

Related U.S. Application Data
(60) Provisional application No. 63/478,908, filed on Jan. 6, 2023.

(51) Int. Cl. H02J 7/00; G01R 31/382

(52) U.S. Cl. CPC H02J 7/0068; G01R 31/382; H02J 2207/20

(57) ABSTRACT

A device is disclosed that includes a battery charge controller having an input removably connected to a power adapter and an output supplying DC current to a battery, a voltage regulator having an input coupled to the output of the battery charge controller and the battery, and a current sensing unit used by the battery charge controller for sensing a charging current to the battery and by the voltage regulator for sensing a discharging current from the battery. Various other methods and systems are also disclosed.

### CROSS REFERENCE TO RELATED APPLICATION

This application claims the benefit of U.S. Provisional Application No. 63/478,908, filed Jan. 6, 2023, the disclosure of which is incorporated, in its entirety, by this reference.

### BACKGROUND

A power distribution/delivery network (PDN) of a device includes various circuits for coupling the device's components to one or more power supplies. The PDN can ensure that power is safely delivered to the intended components. For example, the PDN can include various stages of circuits for converting and/or regulating voltages from different power supplies. These circuits can include components that are necessary for operation but can introduce certain inefficiencies.

For example, a pre-regulator circuit in a PDN employs an integrated current sensing circuit for proper operation and current protections. However, the current sensing circuit introduces power loss and heat generation as well as occupies extra area in the circuit. Removing the current sensing circuit without a replacement can render the pre-regulator circuit unusable.

As such it is desirable to reduce component counts and hence circuit area and power losses in a PDN.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a block diagram of an example battery charger controller.

FIG. 2 is a block diagram of an example battery powered system.

FIG. 3 is a block diagram of an example power management system.

FIG. 4 is a block diagram of another example power management system.

FIG. 5 is a flow diagram of an example method for sharing a current sensing unit.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to a pre-regulator circuit sharing a current sensing circuit with another circuit. As will be explained in greater detail below, implementations of the present disclosure provide for a pre-regulator circuit without its own current sensing circuit and instead being coupled to a current sensing circuit of another circuit in the PDN (e.g., a battery charger circuit). The systems and methods described herein advantageously provide a pre-regulator circuit with improved power efficiency, reduced heat generation, and a smaller area.

Features from any of the implementations described herein can be used in combination with one another in accordance with the general principles described herein. These and other implementations, features, and advantages will be more fully understood upon reading the following detailed description in conjunction with the accompanying drawings and claims.

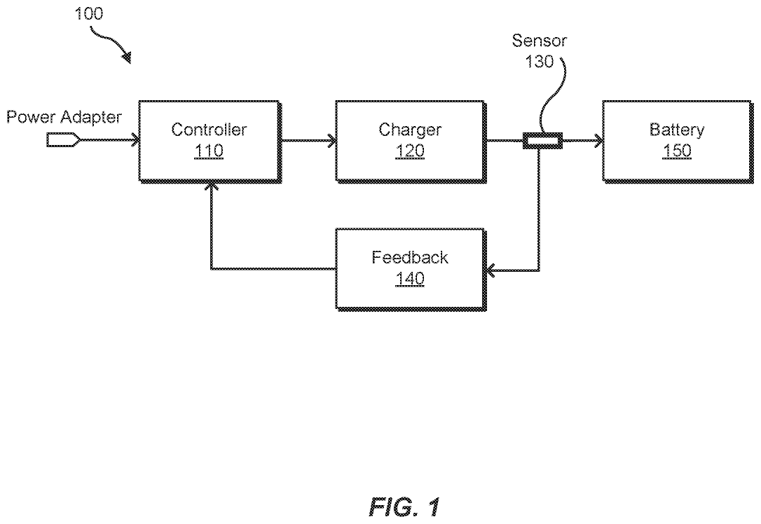

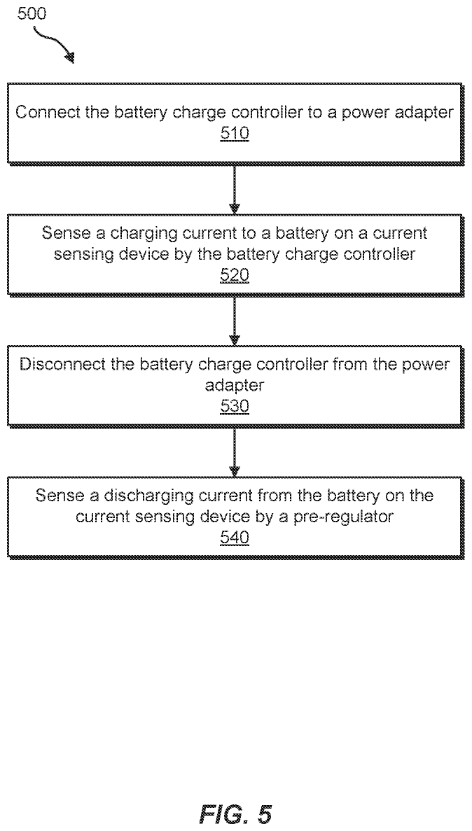

The following will provide, with reference to FIGS. 1-4, detailed descriptions of example systems for power management. Detailed descriptions of corresponding integrated-circuit-implemented methods will also be provided in connection with FIG. 5.

The present disclosure provides an exemplary power management system that includes a battery charge controller having an input removably connected to a power adapter and an output supplying DC current to a battery, a voltage regulator having an input coupled to the output of the battery charge controller and the battery, and a current sensing unit used by the battery charge controller for sensing a charging current to the battery and by the voltage regulator for sensing a discharging current from the battery.

In an implementation, the battery charge controller has a current sense amplifier coupled to the current sensing unit for sensing current flowing through the current sensing unit.

In an implementation, the current sense amplifier of the battery charge controller has two inputs coupled to two terminals of the current sensing unit, respectively.

In an implementation, the output of the battery charge controller is disabled when the input of the battery charge controller is disconnected from the power adapter.

In an implementation, the battery charge controller uses the current sensing unit to sense the charging current when the input of the battery charge controller is connected to the power adapter.

In an implementation, the voltage regulator uses the current sensing unit to sense the discharging current when the input of the battery charge controller is disconnected from the power adapter.

In an implementation, the voltage regulator stops using the current sensing unit when the input of the battery charge controller is connected to the power adaptor.

In an implementation, the voltage regulator has a current sense amplifier coupled to the current sensing unit for sensing current flowing through the current sensing unit.

In an implementation, the current sense amplifier of the voltage regulator has two inputs coupled to two terminals of the current sensing unit, respectively.

In an implementation, the voltage regulator senses a direction of the current flowing through the current sensing unit.

In an implementation, the current sensing unit is a resistor.

In an implementation, the current sensing unit is coupled between the output of the battery charge controller and the battery.

FIG. 1 is a block diagram of an example battery charger controller 100 (e.g., a circuit and/or circuitry for regulating current to protect a battery). The battery charger controller 100 includes a controller 110 (e.g., a control circuit for regulating current based on feedback), a charger 120 (e.g., a power circuit for providing desired voltage and/or current output), a sensor 130 (e.g., a circuit and/or circuitry for sensing one or more conditions and providing a corresponding output) and a feedback element 140 (e.g., a circuit and/or circuitry for providing a feedback signal from an input signal). The controller 110 receives a direct current (DC) power supply from a power adapter and outputs a controlled power to charger 120, for example by regulating the power supply based on feedback from feedback element 140 as will be described further below. Charger 120 generates a desired DC voltage and current based on the output of controller 110 for charging battery 150 (e.g., a rechargeable battery that can in some examples be removable from a device). Examples of charger 120 include voltage regulating circuits, current disabling/shunting circuits, current modulation circuits, etc. The charging current from charger 120 is sensed by sensor 130 and the sensed signal is provided to feedback element 140 which detects the sensed signal and provides a feedback signal to the controller 110. If the charging current exceeds a set level determined by battery 150, feedback element 140 will sense the current via sensor 130 and send a signal to controller 110 to lower the charging current.

In an implementation, sensor 130 can also sense temperature of the battery. Once an overheat is detected by sensor 130, feedback element 140 will send a signal to controller 110 to shut down charger 120. In some examples, sensor 130 and feedback element 140 can continuously sense the current and/or voltage from charger 120 to provide continuous feedback to controller 110. Moreover, in some examples, sensor 130 can further detect conditions of battery 150 for providing feedback via feedback element 140 to controller 110.

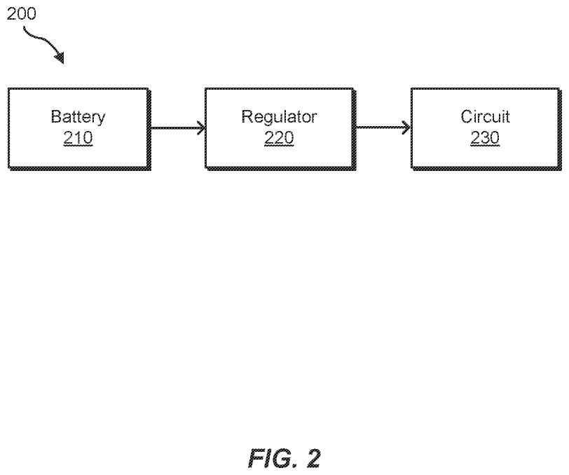

FIG. 2 is a block diagram of an example battery powered system 200 corresponding to a computing device (e.g., a laptop computer, a mobile device, a desktop computer, a server, a tablet device, a smartphone, a wearable device, an augmented reality device, a virtual reality device, a network device, and/or an electronic device powered by a rechargeable battery). The battery powered system 200 includes a battery 210, a regulator 220 (e.g., a circuit and/or circuitry for regulating voltage when current varies), and a circuit 230 (e.g., corresponding to or generally representing power consumption components including a processor and memory of a device such as a laptop computer and/or a mobile device). Regulator 220 receives power from battery 210 and automatically maintains a constant voltage, albeit with current fluctuations, to circuit 230. The current drawn by circuit 230 fluctuates because circuit 230 can have more or less components activated. For example, when system 200 is in a sleep mode, it draws very little current as circuit 230 (e.g., a processor thereof) can be powered down or otherwise throttled. When system 200 performs a heavy workload such as playing a video, circuit 230 (e.g., the processor) draws a large amount of current for video processing. High current can bring down the supply voltage and cause system 200 to malfunction if the supply voltage is not regulated. Therefore, regulator 220 maintains a substantially constant voltage under wide current fluctuations.

In implementations, regulator 220 uses a simple feed-forward design (i.e., no feedback) or includes a negative feedback (e.g., when output voltage of regulator 220 increases, the negative feedback brings down the input voltage of regulator 220 to maintain the output voltage constant). When feedback is employed, voltage and current at circuit 230 are sensed and induce a feedback signal to regulate voltage outputs of regulator 220.

In implementations, regulator 220 includes a pre-regulator (not shown) to reduce ripples (e.g., current fluctuations) in the output of regulator 220 or to minimize power dissipation of regulator 220. In this implementation, the pre-regulator uses a current sensor to detect current drawn from battery 210. However, the current sensor itself can produce certain inefficiencies, such as power loss, heat, as well as increase fabrication cost and/or area needed for circuits. Moreover, as multiple power regulating circuits can have integrated current sensors, such inefficiencies can compound.

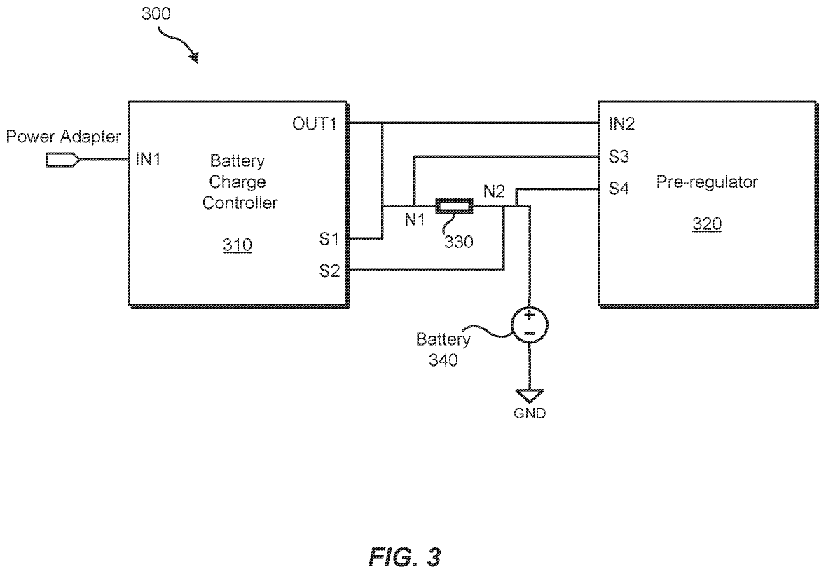

FIG. 3 is a block diagram of an example power management system 300. Power management system 300 includes a battery charge controller 310, a pre-regulator 320, and a current sensing unit 330 for charging and regulating power supplied from a battery 340. Battery charge controller 310 has an input terminal IN1 removably connected to a power adapter (not shown) which can supply a direct current (DC) power between, for example, 3.5 V to 24 V. When input terminal IN1 is connected to the power adapter, battery charge controller 310 outputs a controlled DC power of a designated voltage (e.g., 5 V) at an output terminal OUT1. Output terminal OUT1 is coupled to battery 340 through current sensing unit 330 for charging battery 340. Output terminal OUT1 is also connected to an input terminal IN2 of pre-regulator 320 for supplying the controlled DC power to pre-regulator 320. Pre-regulator 320 is a circuit that performs preliminary voltage regulation before feeding its output to a final regulator. An exemplary pre-regulator can be a divided-by-2 (Div2) or a divided-by-4 (Div4) pre-regulator that regulates voltages. Outputs from pre-regulator 320 are supplied to a regulator (e.g., regulator 220, not shown in FIG. 3) and then to an electronic system (e.g., circuit 230, not shown in FIG. 3) that consumes the DC power.

In implementations, pre-regulator 320 and the regulator are integrated, and both use current sensing unit 330.

Referring again to FIG. 3, battery charge controller 310 has input terminals S1 and S2 connected to current sensing unit 330 at nodes N1 and N2, respectively. In an implementation, current sensing unit 330 is a resistor, and input terminals S1 and S2 are coupled to a positive input and a negative input, respectively, of a charge current sense amplifier (not shown) inside battery charge controller 310. With the charge current sensing, battery charge controller 310 can set a charge current range to protect battery 340.

Referring again to FIG. 3, current sensing unit 330 is also connected to pre-regulator 320 at input terminals S3 and S4. In the above implementation in which current sensing unit 330 is a resistor, pre-regulator 320 also employs an internal current sense amplifier (not shown) with input terminals S3 and S4 coupled to a negative and positive input, respectively, of the internal current sense amplifier. In implementations, pre-regulator 320 uses the sensed current for circuit protection, such as overcurrent protection and reverse current protection (applying to, e.g., a non-multimode Div2 pre-regulator) and controlling mode transitions (applying to, e.g., a multimode Div2 pre-regulator).

Referring again to FIG. 3, during a battery charging operation, i.e., battery charge controller 310 is connected to a power adapter, DC current flows from OUT1 of battery charge controller 310 through current sensing unit 330 to battery 340 for charging battery 340. DC current also flows from OUT1 of battery charge controller 310 to IN2 of pre-regulator 320 to supply power to the electronic system. During this operation, pre-regulator 320, such as a Div2, enters into 1:1 mode by a system level command (e.g., from a power management controller), thus does not need to monitor current because of the system override. Therefore, the current sensing unit 330 is only used by battery charge controller 310 when the power adapter is connected.

In an implementation, a system level command can de-activate current sense amplifier of pre-regulator 320 when the power adapter is connected.

During a battery powered operation, i.e., battery charge controller 310 is not connected to a power adapter and battery 340 is in discharging mode, DC current flows from battery 340 through current sensing unit 330 to IN2 of pre-regulator 320. In the battery discharging mode, battery charge controller 310 is not active, i.e., the output terminal OUT1 is disabled, thus not using the current sensing unit 330. Therefore, current sensing unit 330 shared by battery charge controller 310 and pre-regulator 320 is utilized differently in different operations.

However, because the current sense amplifier of either battery charge controller 310 or pre-regulator 320 has high input impedance, connecting both current sense amplifiers to current sensing unit 330 does not interfere current sensing by either one. In an implementation, the two current sense amplifiers can be merged, i.e., battery charge controller 310 and pre-regulator 320 share one current sense amplifier in addition to sharing one current sensing unit 330.

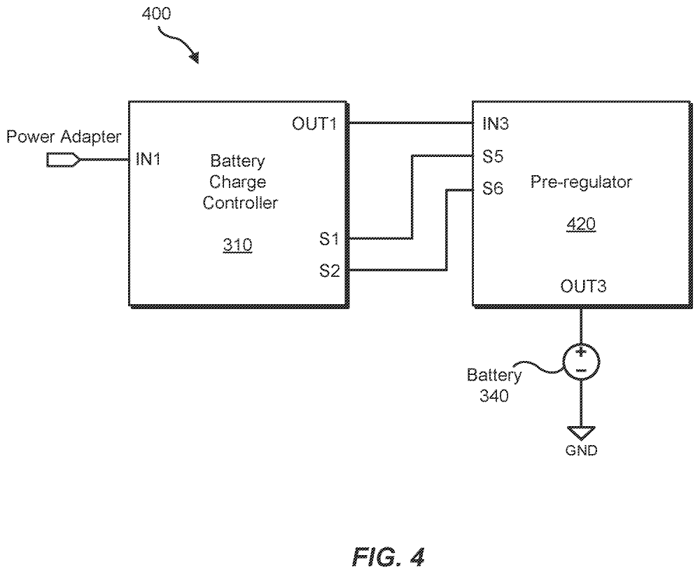

In another implementation, current sensing unit 330 includes a field effect transistor (FET) with a source and drain connected to nodes N1 and N2, respectively. In some implementations, current sensing unit 330 can be integrated with either battery charge controller 310 and/or pre-regulator 320 (as will be described further below with respect to FIG. 4). In other implementations, current sensing unit 330 can be integrated with and/or used by another power delivery circuit.

FIG. 4 is a block diagram of another example power management system 400. Power management system 400 includes battery charge controller 310 and a pre-regulator 420 for charging and regulating power supplied from a battery 340. Battery charge controller 310 has an input terminal IN1 removably connected to a power adapter (not shown) which can supply a direct current (DC) power between, for example, 3.5 V to 24 V. When input terminal IN1 is connected to the power adapter, battery charge controller 310 outputs a controlled DC power of a designated voltage (e.g., 5 V) at an output terminal OUT1. Output terminal OUT1 is coupled to an input terminal IN3 of pre-regulator 420. Pre-regulator 420 has an output terminal OUT3 coupled to battery 340. In an implementation, the DC power supplied by battery charge controller 310 is passed to battery 340 through input terminal IN3 and output terminal OUT3 of pre-regulator 420. The DC power is used for charging battery 340.

In an implementation, pre-regulator 420 includes a current sensor (not shown) for detecting battery charging current as well as battery supply current similar to current sensing unit 330 depicted in FIG. 3 and associated descriptions. However, the current sensor of FIG. 4 is integrated in pre-regulator 420.

In an implementation, the current sensor is coupled to battery charge controller 310 through terminals S5 and S6 of pre-regulator 420 and terminals S1 and S2 of battery charge controller 310. Therefore, the current sensor is shared by pre-regulator 420 and battery charge controller 310 similar to power management system 300 shown in FIG. 3. In other implementations, battery charge controller 310 can include the current sensor, which can be coupled to pre-regulator 420 through terminals S1 and S2 of battery charge controller 310 and terminals S5 and S6 of pre-regulator 420.

FIG. 5 is a flow diagram of an example method 500 for sharing a current sensing unit by battery charge controller 310 and pre-regulator 320 (shown in FIG. 3). Method 500 begins with connecting battery charge controller 310 to a power adapter in block 510. Battery charge controller 310 is removably connected to a power adapter which supplies a DC power. Battery charge controller 310 uses current sensing unit 330 to sense a charging current to battery 340 in block 520. In an implementation, battery charge controller 310 uses current sensing unit 330 to detect the charging current when an input of battery charge controller 310 is connected to the power adapter. When battery charge controller 310 is disconnected from the power adapter in block 530, pre-regulator 320 uses the same current sensing unit 330 to sense a discharging current from the battery in block 540. At the same time, in an implementation, battery charge controller 310 is disabled, thus not using current sensing unit 330. In an implementation, pre-regulator 320 stops using current sensing unit 330 when the input of battery charge controller 310 is connected to the power adaptor, so that current sensing unit 330 is used by either battery charge controller 310 or pre-regulator 320 but not both.

The presently disclosed exemplary power management system that uses just one current sensing unit to be used by both a battery charge controller and a voltage regulator including a pre-regulator, so that device count as well as power consumption are reduced.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a battery charge controller coupled to a battery;
a voltage regulator coupled to the battery; and
a current sensing unit used by the battery charge controller for sensing a charging current to the battery and by the voltage regulator for sensing a discharging current from the battery.

2. The device of claim 1, wherein the battery charge controller uses the current sensing unit to sense the charging current when a first input of the battery charge controller is connected to a power adapter.

3. The device of claim 1, wherein the voltage regulator uses the current sensing unit to sense the discharging current when a first input of the battery charge controller is disconnected from a power adapter.

4. The device of claim 1, wherein the voltage regulator stops using the current sensing unit when a first input of the battery charge controller is connected to a power adapter.

5. The device of claim 1, wherein an output of the battery charge controller is disabled when a first input of the battery charge controller is disconnected from a power adapter.

6. The device of claim 1, wherein the current sensing unit is coupled between an output of the battery charge controller and the battery.

7. The device of claim 1, wherein the battery charge controller has a current sense amplifier coupled to the current sensing unit for sensing current flowing through the current sensing unit.

8. The device of claim 7, wherein the current sense amplifier has two inputs coupled to two terminals of the current sensing unit, respectively.

9. The device of claim 1, wherein the voltage regulator has a current sense amplifier coupled to the current sensing unit for sensing current flowing through the current sensing unit.

10. The device of claim 9, wherein the current sense amplifier has two inputs coupled to two terminals of the current sensing unit, respectively.

11. The device of claim 1, wherein the voltage regulator senses a direction of the current flowing through the current sensing unit.

12. The device of claim 1, wherein the current sensing unit is a resistor.

13. A system comprising:
a battery charge controller having a first input removably connected to a power adapter and an output supplying DC current to a battery;
a voltage regulator having a second input coupled to the output of the battery charge controller and the battery; and
a current sensing unit coupled between the output of the battery charge controller and the battery, the current sensing unit being used by the battery charge controller for sensing a charging current to the battery and by the voltage regulator for sensing a discharging current from the battery.

14. The system of claim 13, wherein the current sensing unit is coupled between the output of the battery charge controller and the battery.

15. The system of claim 13, wherein the battery charge controller uses the current sensing unit to sense the charging current when the first input of the battery charge controller is connected to the power adapter.

16. The system of claim 13, wherein the voltage regulator uses the current sensing unit to sense the discharging current when the first input of the battery charge controller is disconnected from the power adapter.

17. A method, comprising:
sensing a charging current to a battery on a current sensing unit by a battery charge controller; and
sensing a discharging current from the battery on the current sensing unit by a voltage regulator.

18. The method of claim 17, wherein the battery charge controller uses the current sensing unit to sense the charging current when an input of the battery charge controller is connected to a power adapter.

19. The method of claim 17, wherein the voltage regulator uses the current sensing unit to sense the discharging current when an input of the battery charge controller is disconnected from a power adapter.

20. The method of claim 17, wherein the voltage regulator stops using the current sensing unit when an input of the battery charge controller is connected to a power adaptor.
